(19) United States
(12) Patent Application Publication
(10) Pub. No.: US 2006/0110940 A1
(43) Pub. Date: May 25, 2006

(54) Method of preparing mesoporous thin film having low dielectric constant

(75) Inventors: Jong Baek Seon, Yeongin-si (KR); Hyeon Jin Shin, Suwon-si (KR); Hyun Dam Jeong, Suwon-si (KR); Ji Man Kim, Suwon-si (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Corning Co., Ltd., Suwon-si (KR)

(21) Appl. No.: 11/283,926

(22) Filed: Nov. 22, 2005

(30) Foreign Application Priority Data
Nov. 24, 2004 (KR) 2004-96830

(51) Int. Cl. H01L 21/469

(52) U.S. Cl. 438/780; 438/790; 438/783

(57) ABSTRACT

A method of preparing a mesoporous thin film having a low dielectric constant, which includes mixing a cyclic siloxane-based monomer, an organic solvent, an acid catalyst or a base catalyst, and water, to prepare a coating solution, which is then applied on a substrate and heat cured. The mesoporous thin film of the current invention may exhibit excellent physical properties including hardness and elastic modulus, and may have a low dielectric constant of 2.5 or less, and thus, may be used to manufacture semiconductors.

This non-provisional application claims priority under 35 U.S.C. § 119(a) on Korean Patent Application No. 2004-96830 filed on Nov. 24, 2004 which is herein incorporated by reference.

### BACKGROUND OF THE INVENTION

1. Field of the Invention

Embodiments of the present invention relate, generally, to a method of preparing a mesoporous thin film having a low dielectric constant, and more specifically, to a method of preparing a mesoporous thin film having a low dielectric constant and excellent physical properties by using a cyclic siloxane-based monomer as a structure-directing agent.

2. Description of the Related Art

With developments of techniques for fabricating semiconductors, semiconductor devices have been manufactured to be miniaturized and more and more highly integrated. However, in the highly integrated semiconductor, signal transmission may be impeded due to interference between metal wires. Thus, the highly integrated semiconductor exhibits performance that depends on a signal transmission speed through the wiring. In order to lower resistance and capacitance of the metal wire, it is required to reduce the capacitance of an interlayer insulating film in the semiconductor.

Although a silicon oxidation film having a dielectric constant of about 4.0 has been typically used as the interlayer insulating film of the semiconductor, it has reached its functional limits due to increase of the integration of the semiconductor. Therefore, attempts to decrease the dielectric constant of the insulating film have been made. In this regard, U.S. Pat. Nos. 3,615,272, 4,399,266, 4,756,977, and 4,999,397 disclose methods of manufacturing an interlayer insulating film of a semiconductor using polysilsesquioxane having a dielectric constant of about 2.5 to 3.1, by means of SOD (Spin On Deposition).

Further, with the aim of reduction of the dielectric constant of the interlayer insulating film of the semiconductor to 3.0 or less, a porogen-template method has been proposed, which includes mixing a siloxane-based resin with a porogen, and pyrolyzing the porogen at a high temperature of 250-350° C. to remove it.

U.S. Pat. Nos. 5,057,296 and 5,102,643 disclose a mesoporous molecular sieve material manufactured by using an ionic surfactant as a structure-directing agent. The mesoporous material, which is composed of 2-50 nm sized mesopores, has high adsorptivity of atoms or molecules due to its large surface area. In addition, since the pores of the mesoporous material are formed in uniform sizes, the mesoporous material is usable as a molecular sieve. Moreover, the mesoporous material is expected to be variously applied to interlayer insulating films having a dielectric constant of 3.0 or less, conductive materials, display materials, chemical sensors, fine chemical- and bio-catalysts, insulators, and packaging materials.

U.S. Pat. No. 6,270,846 discloses a method of manufacturing a porous, surfactant-templated thin film, which includes mixing a silane monomer, a solvent, water, a surfactant and a hydrophobic polymer, applying the mixture on a substrate, and evaporating a portion of the solvent to form a thin film, which is then heated.

U.S. Pat. No. 6,329,017 discloses a method of manufacturing a mesoporous thin film, including mixing a silica precursor as a silane monomer with an aqueous solvent, a catalyst and a surfactant, to prepare a precursor solution, spin coating a predetermined film with the precursor solution, and removing the aqueous solvent.

U.S. Pat. No. 6,387,453 discloses a method of manufacturing a mesoporous material, including mixing a precursor sol, a solvent, a surfactant and an interstitial compound, to prepare a silica sol, and evaporating a portion of the solvent from the silica sol.

However, since the above methods of manufacturing the mesoporous thin film using the surfactant as the template use the silane monomer, water and an acid, the dielectric constant is not decreased to a desired level due to the moisture absorbency generated during the manufacturing process. In addition, the quality of the thin film is drastically lowered to the extent that the dielectric constant cannot be measured. Hence, to solve the problems caused by moisture absorbency, conventional methods including calcination and hexamethyldisilazane treatment have been employed.

However, the conventional methods have complicated processes due to additional moisture absorption prevention and polymerization, thus increasing manufacturing costs.

### OBJECTS AND SUMMARY

Accordingly, embodiments of the present invention has been made keeping in mind the above problems occurring in the related art, and an object of embodiments of the present invention is to provide a method of preparing a mesoporous thin film having a low dielectric constant, in which a cyclic siloxane-based monomer is used to form an ordered mesoporous thin film having low moisture absorbency, thus realizing a sufficiently low dielectric constant of 2.5 or less and superb mechanical properties including elastic modulus and hardness.

Another object of embodiments of the present invention is to provide a method of preparing a mesoporous thin film having a low dielectric constant, which is advantageous because it has low preparation costs due to a simplified preparation process, without the need for moisture absorption prevention and polymerization of a siloxane-based monomer.

In order to accomplish the above objects, embodiments of the present invention provide a method of preparing a mesoporous thin film, including the first step of mixing a cyclic siloxane-based monomer, an organic solvent, an acid catalyst or a base catalyst, and water, to prepare a coating solution, and the second step of applying the coating solution on a substrate, and heat curing the coating solution applied on the substrate, to obtain a mesoporous thin film.

### BRIEF DESCRIPTION OF THE DRAWINGS

The above and other objects, features and advantages of embodiments of the present invention will be more clearly understood from the following detailed description taken in conjunction with the accompanying drawings, in which:

FIG. 1 shows a TEM image of an ordered mesoporous thin film prepared according to an embodiment of the present invention;

FIG. 2 shows an X-ray diffraction pattern of the mesoporous thin film prepared according to an embodiment of the present invention; and

FIG. 3 shows the measurement results of absorbance of mesoporous thin films prepared according to an embodiment of the present invention, using an FTIR (Fourier Transform InfraRed) spectrometer.

### DETAILED DESCRIPTION OF THE PREFERRED EMBODIMENTS

Hereinafter, a detailed description will be given of embodiments of the present invention, with reference to the appended drawings.

A conventional method of preparing a thin film using a monomer undesirably manifests low quality and high moisture absorbency, and thus, includes polymerizing the monomer. However, in embodiments of the present invention, the moisture absorbency of the thin film, which seems to be caused by the structural properties of the monomer, may be decreased by using a cyclic siloxane-based monomer having a higher molecular weight and relatively fewer reactive —OH groups at a terminal moiety thereof than commercially available monomers.

Therefore, embodiments of the present invention provide a method of preparing a mesoporous thin film having a low dielectric constant, which includes mixing at least one cyclic siloxane-based monomer selected from the group consisting of monomers represented by Formula 1, 2 and 3, below, an organic solvent, an acid catalyst or a base catalyst, and water, to prepare a coating solution. As such, the cyclic siloxane-based monomer may include at least one selected from the group consisting of a compound represented by Formula 1, a compound represented by Formula 2, a compound represented by Formula 3, and combinations thereof. In addition, a porogen may be used to form the pores in the thin film. In particular, when a surfactant is used as the porogen, it is possible to prepare a thin film having an ordered structure.

Then, the coating solution thus obtained may be applied on a substrate and heat cured, to obtain a mesoporous thin film.

Usable in embodiments of the present invention, the cyclic siloxane-based monomer is a cyclic siloxane-based monomer represented by Formula 1, 2 or 3 or mixture thereof, below:

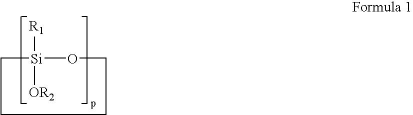

wherein R₁ is a hydrogen atom, a C1 to C3 alkyl group, or a C6 to C15 aryl group; R₂ is a hydrogen atom, a C1 to C10 alkyl group, or SiX₁X₂X₃ (in which X₁, X₂ and X₃ are independently each a hydrogen atom, a C1 to C3 alkyl group, a C1 to C10 alkoxy group, or a halogen atom); and p is an integer ranging from 3 to 8;

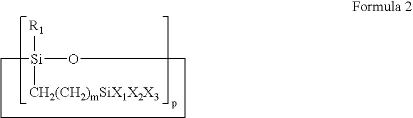

wherein R₁ is a hydrogen atom, a C1 to C3 alkyl group, or a C6 to C15 aryl group; X₁, X₂ and X₃ are independently each a hydrogen atom, a C1 to C3 alkyl group, a C1 to C10 alkoxy group, or a halogen atom, at least one of which is a hydrolyzable functional group; and m is an integer ranging from 0 to 10, and p is an integer ranging from 3 to 8; and

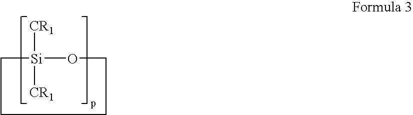

wherein R₁ is a hydrogen atom, a C1 to C3 alkyl group, R′CO (in which R′ is a C1 to C3 alkyl group), a halogen atom, or SiX₁X₂X₃ (in which X₁, X₂ and X₃ are independently each a hydrogen atom, a C1 to C3 alkyl group, a C1 to C10 alkoxy group, or a halogen atom, at least one of which is a hydrolyzable functional group); and p is an integer ranging from 3 to 8.

When preparing a coating solution in embodiments of the present invention, in addition to the monomer of Formula 1, 2 or 3, an Si monomer having an organic bridge represented by Formula 4, below, or an acyclic alkoxy silane monomer represented by Formula 5, below, may be used:
X₃X₂X₁Si-M-SiX₁X₂X₃ Formula 4

wherein X₁, X₂ and X₃ are independently each a hydrogen atom, a C1 to C3 alkyl group, a C1 to C10 alkoxy group, or a halogen atom, at least one of which is a hydrolyzable functional group; and M is a single bond, a C1 to C10 alkylene group, or a C6 to C15 arylene group; and
(R₁)ₙSi(OR₂)₄₋ₙ Formula 5

wherein R₁ is a hydrogen atom, a C1 to C3 alkyl group, a halogen group, or a C6 to C15 aryl group, and R₂ is a hydrogen atom, a C1 to C3 alkyl group, or a C6 to C15 aryl group, at least one of R₁ and OR₂ is a hydrolyzable functional group; and n is an integer ranging from 0 to 3. Either or both of the monomers represented by Formulas 4 and 5 may be added to a coating solution of embodiments of the present invention.

According to embodiments of the present invention, the cyclic siloxane-based monomer of Formula 1 preferably includes, for example, a compound (TS-T4Q4) represented by Formula 6, below, obtained when R₁ is methyl, R₂ is Si(OCH₃)₃, and p is 4 in Formula 1; a compound (TS-T4(OH)) represented by Formula 7, below, obtained when R₁ is methyl, R₂ is hydrogen, and p is 4 in Formula 1; a compound (TS-T4(OMe)) represented by Formula 8, below, obtained when R₁ and R₂ are methyl, and p is 4 in Formula 1; a compound (TS-T4T4) represented by Formula 9, below, obtained when R₁ is methyl, R₂ is SiCH₃(OCH₃)₂, and p is 4 in Formula 1; a compound represented by Formula 10, below, obtained when R₁ is methyl, R₂ is Si(CH₃)₂(OCH₃), and p is 4 in Formula 1; or a compound represented by Formula 11, below, obtained when R₁ is methyl, R₂ is Si(CH₃)₃, and p is 4 in Formula 1:

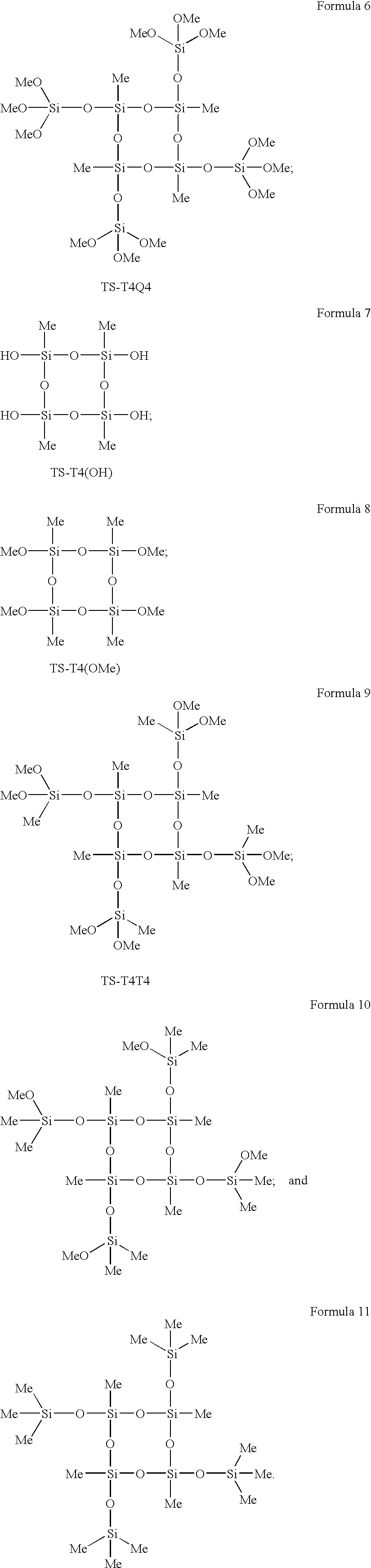

In addition, the cyclic siloxane-based monomer of Formula 2 preferably includes, for example, a compound represented by Formula 12, below:

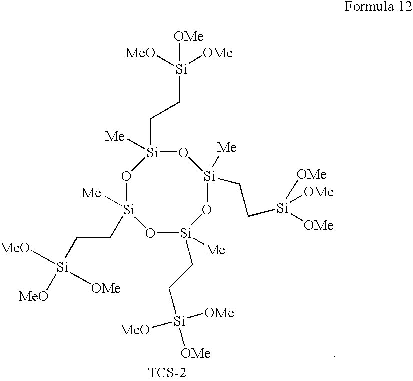

In addition, the cyclic siloxane-based monomer of Formula 3 preferably includes, for example, a compound represented by Formula 13, below, obtained when R₁ is methyl and p is 4 in Formula 3:

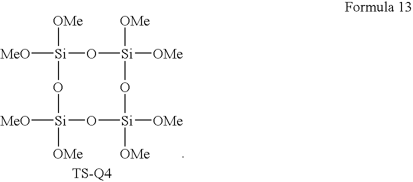

Further, the Si monomer having an organic bridge of Formula 4 preferably includes, for example, a compound represented by Formula 14 or 15, below:

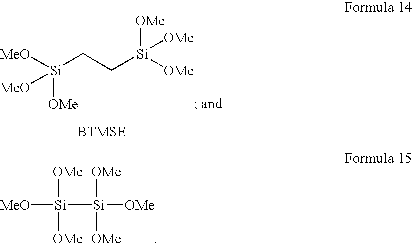

Furthermore, the acyclic alkoxy silane monomer of Formula 5 preferably includes, for example, a compound represented by Formula 16, 17 or 18, below:

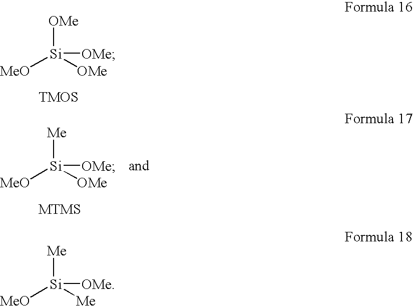

The porogen used in embodiments of the present invention includes all of the porogens known for use in the formation of a porous insulating film. Specifically, polycaprolactone, α-cyclodextrin, β-cyclodextrin, or γ-cyclodextrin may be included, but the porogen is not limited thereto.

In embodiments of the present invention, examples of a surfactant, which may be used as the porogen, include, but are not limited to, anionic surfactants, cationic surfactants, and nonionic surfactants or block copolymers. Examples of the anionic surfactant include, but are not limited to, sulfates, sulfonates, phosphates, or carboxylic acids. Examples of the cationic surfactant include, but are not limited to, alkylammonium salts, Gemini surfactants, cetylethylpiperidinium salts, or dialkyldimethylammonium. Examples of the nonionic surfactant include, but are not limited to, any one selected from the group consisting of primary amines, poly(oxyethylene)oxide, octaethylene glycol monodecyl ether, octaethylene glycol monohexadecyl ether, and block copolymers. The porogen is preferably used in an amount of 0.01 to 70 wt %, based on the total weight of the siloxane-based monomer and the porogen in the coating solution, but is not limited thereto. Preferably, the surfactant includes any one selected from the group consisting of Brij-based surfactants, polyethyleneglycol-polypropyleneglycol-polyethyleneglycol block terpolymer, cetyltrimethylammonium bromide (CTAB), octylphenoxypolyethoxy(9-10)ethanol (Triton X-100), and ethylenediamine alkoxylate block copolymer.

In the case where the surfactant is used as the porogen, the evaporation of the solvent from the coating solution applied on the substrate may induce the micellation of the surfactant. Such a surfactant is continuously self-assembled through calcination, thus forming a hybrid monomer-surfactant mesophase. Thereby, a film having a long range ordered structure or a short range ordered structure may be obtained.

Examples of the organic solvent used in embodiments of the present invention include, but are not particularly limited to, aliphatic hydrocarbon solvents, such as hexane, heptane, etc.; aromatic hydrocarbon solvents, such as anisole, mesitylene, xylene, etc.; ketone-based solvents, such as methyl isobutyl ketone, 1-methyl-2-pyrrolidinone, cyclohexanone, acetone, etc.; ether-based solvents, such as tetrahydrofuran, isopropyl ether, etc.; acetate-based solvents, such as ethyl acetate, butyl acetate, propylene glycol methyl ether acetate, etc.; alcohol-based solvents, such as isopropyl alcohol, butyl alcohol, etc.; amide-based solvents, such as dimethylacetamide, dimethylformamide, etc.; silicon-based solvents; or combinations thereof.

Although the solid content of the coating solution is not particularly limited, it may correspond to 5 to 70 wt %, based on the total weight of the coating solution.

In the acid catalyst or base catalyst usable in embodiments of the present invention, the acid catalyst may include all of the acid catalysts known for preparation of polysilsesquioxane, and is not particularly limited. Examples of the acid catalyst include, but are not limited to, hydrochloric acid, nitric acid, benzene sulfonic acid, oxalic acid, formic acid or combinations thereof. The base catalyst of embodiments of the present invention may include all of the base catalysts known for preparation of polysilsesquioxane, and is not particularly limited. Examples of the base catalyst include, but are not limited to, potassium hydroxide, sodium hydroxide, triethylamine, sodium bicarbonate, pyridine or combinations thereof.

The substrate is not particularly limited so long as it does not hinder the purposes of embodiments of the present invention. Any substrate that is able to endure heat curing conditions may be used, and includes, for example, a glass substrate, a silicon wafer, a plastic substrate, etc., depending on end uses. Moreover, a process of coating the substrate with the coating solution includes, for example, spin coating, dip coating, spray coating, flow coating, and screen printing, but is not limited thereto. Of these coating processes, a spin coating process is preferable in terms of convenience and uniformity. In the case of performing the spin coating process, the spin rate is preferably controlled in the range of from 800 to 5,000 rpm.

After the completion of the coating process, a process of evaporating the solvent to dry the film may be further included, if required. As such, the film may be dried by simply exposing it to external environments, initially curing it in a vacuum atmosphere, or heating it to a relatively low temperature of 200° C. or less.

Subsequently, the film is heat cured at 25 to 600° C. for 1 min to 24 hrs, forming an insoluble film having no cracks. As such, the term ‘film having no cracks' means that cracks on a film are not observed by the naked eye when the film is magnified 1000× using an optical microscope, and the term ‘insoluble film’ means that a film coated with a solvent or resin used to deposit a siloxane-based polymer to form a desired film is not essentially dissolved in the above solvent or resin.

When the porogen is included, the heat curing temperature is determined in consideration of the decomposition temperature of the porogen. Particularly, in the case where the ordered structure is formed using the above-mentioned surfactant, ordering effects may be further increased as a heat curing time is prolonged at a low heat curing temperature. When a drastic temperature increase is observed at a temperature not less than the evaporation temperature of the solvent, the structure of the thin film may become disordered.

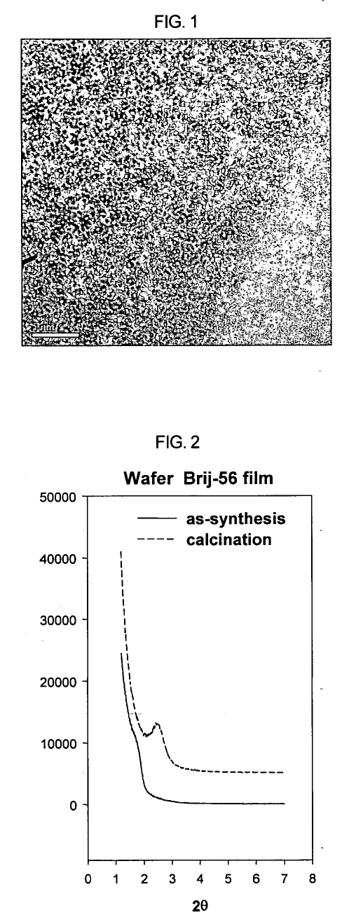

The mesoporous thin film prepared by the method of embodiments of the present invention may have an ordered monodispersed pore array. The ordered film manifests two-dimensional regularity as shown in the TEM image of FIG. 1.

FIG. 2 shows the X-ray diffraction peak of the mesoporous thin film prepared by the method of an embodiment of the present invention. As seen in FIG. 2, the ordered film has a single peak or multiple peaks at 2θ=0.3-10°. Thus, a mesoporous thin film having a low dielectric constant of embodiments of the present invention may serve as the interlayer insulating film of the semiconductor, and as well, may be widely applied to conductive materials, display materials, chemical sensors, bio-catalysts, insulators, and packaging materials.

A better understanding of embodiments of the present invention may be obtained in light of the following examples which are set forth to illustrate, but are not to be construed to limit the present invention.

Synthesis Of Multi-Reactive Cyclic Siloxane Monomer

### SYNTHESIS EXAMPLE 1

Synthesis Of Monomer Of Formula 6

41.6 mmol (10.00 g) of 2,4,6,8-tetramethyl-2,4,6,8-cyclotetrasiloxane were loaded into a flask, and then diluted with 100 ml of tetrahydrofuran (THF). To this reaction solution, 700 mg of 10 wt % Pd/C (palladium/charcoal) were added, and thereafter, 177.8 mmol (3.20 ml) of distilled water were added. At this time, the generated hydrogen gas was removed. The reaction occurred at room temperature for 5 hrs, after which the resultant reaction solution was filtered using a celite and MgSO₄. The filtrate was allowed to stand at a pressure reduced to about 0.1 torr to remove the volatile material therefrom, thus yielding a colorless liquid monomer represented by Formula 7, below:

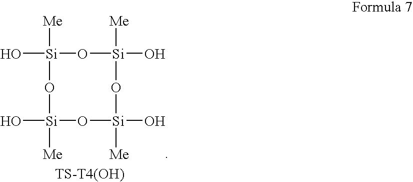

41.6 mmol (12.6 g) of the compound of Formula 7 were diluted with 200 ml of THF to obtain a diluted solution, to which 177.8 mmol (13.83 g) of triethylamine were added. The temperature of the solution was decreased to 0° C., and then 177.8 mmol of chlorotrimethoxysilane were slowly added to the solution. While the temperature of the solution was gradually increased to room temperature, the reaction took place for 12 hrs. The resultant reaction solution was filtered using a celite, and the filtrate was allowed to stand at a pressure reduced to about 0.1 torr to remove the volatile material therefrom, thus yielding a compound represented by Formula 6, below:

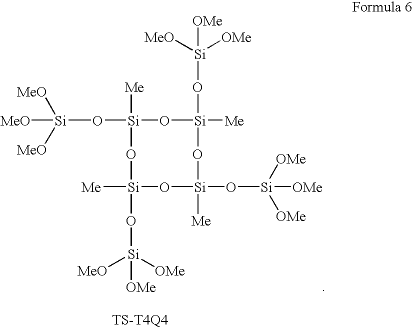

1H-NMR (300 MHz) of the synthesized monomer was measured: δ 0.092(s, 12H,4×[—CH3]), 3.58 (s, 36H,4×[—OCH3]3).

### SYNTHESIS EXAMPLE 2

Synthesis Of Monomer Of Formula 12

A solution of 29.01 mmol (10.0 g) of 2,4,6,8-tetramethyl-2,4,6,8-tetravinylcyclotetrasiloxane dissolved along with 0.164 g of platinum(0)-1,3-divinyl-1,1,3,3-tetramethyldisiloxane complex solution in xylene was loaded into a flask, and then diluted with 300 ml of diethylether. The temperature of the solution was decreased to −78° C., and subsequently, 127.66 mmol (17.29 g) of trichlorosilane were slowly added to the solution. While the temperature of the solution was gradually increased to room temperature, the reaction took place for 40 hrs. The resultant reaction solution was allowed to stand at a pressure reduced to about 0.1 torr to remove the volatile material therefrom, thereby concentrating the solution. The concentrated solution was added with 100 ml of hexane, stirred for 1 hr, and then filtered using a celite. The obtained filtrate was allowed to stand at a pressure reduced to about 0.1 torr to remove hexane therefrom, yielding a liquid reaction product. 11.56 mmol (10.0 g) of the liquid reaction product were diluted with 50 ml of THF, to which 138.71 mmol (13.83 g) of triethylamine were added. The reaction temperature was decreased to −78° C., and 136.71 mmol (4.38 g) of methylalcohol were slowly added to the reaction solution. The reaction temperature was gradually increased to room temperature, and the reaction occurred for 15 hrs. The reaction solution was filtered using a celite, after the filtrate was allowed to stand at a pressure reduced to about 0.1 torr to remove the volatile material therefrom, thus concentrating the filtrate. The concentrated solution was mixed with 100 ml of hexane, stirred for 1 hr, and filtered again using a celite. 5 g of activated carbon were added to the filtrate, followed by stirring the filtrate for 10 hrs and filtering the stirred filtrate using a celite. The obtained filtrate was allowed to stand at a pressure reduced to about 0.1 torr to remove hexane therefrom, thereby yielding a colorless liquid monomer represented by Formula 12, below:

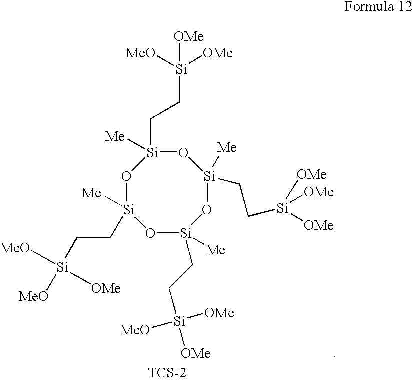

1H-NMR (300 MHz) of the synthesized monomer was measured (acetone-d6 solution): δ 0.09(s, 12H, 4×[—CH3]), 0.52-0.64(m, 16H, 4×[—CH2CH2—]), 3.58(s, 36H, 4×[—OCH3]3).

### PREPARATIVE EXAMPLE 1

Preparation Of Insulating Film

The monomer of Formula 6 obtained in Synthetic Example 1 was dissolved in 0.5 g of Brij-56 in 10 g of ethanol, to which 0.86 g of 0.1 M dilute HCl aqueous solution was added. The monomer solution was stirred until being completely uniform, to prepare a coating solution for use in manufacturing a mesoporous thin film. The coating solution was spin applied on a silicon wafer at 3000 rpm for 30 sec, pre-heated at 83° C. for 1 min and then 250° C. for 1 min on a hot plate in a nitrogen atmosphere, and dried, to prepare a film. The film was heat treated at 400° C. (temperature increase rate: 3° C./min) for 1 hr in a vacuum atmosphere, to manufacture an insulating film. Thereafter, thickness, dielectric constant, hardness and elastic modulus of the obtained insulating film were measured. In addition, whether an X-ray diffraction (XRD) peak had been generated was confirmed. The results are shown in Table 2, below.

### PREPARATIVE EXAMPLES 2 TO 21

Preparation of Insulating Films

Respective thin films were prepared in the same manner as in Example 1, with the exception that the kind of siloxane monomer, porogen and solvent, and the pre-heating conditions and the calcination conditions, were changed as shown in Table 1, below. The physical properties of the thin films were measured. The results are given in Table 2, below.

[Measurement of Physical Properties]

The physical properties of the insulating film were assayed in accordance with the following procedures.

1) Dielectric Constant

A silicon heat oxidation film was applied to a thickness of 3000 Å on a boron-doped p-type silicon wafer, and a 100 Å thick titanium layer, a 2000 Å thick aluminum layer, and a 100 Å thick titanium layer were sequentially deposited on the silicon film using a metal evaporator. Subsequently, an insulating film was formed on the outermost metal layer. On the insulating film, a 100 Å thick circular titanium thin film and a 5000 Å thick circular aluminum thin film, each having a diameter of 1 mm, were deposited, using a hard mask designed to have an electrode diameter of 1 mm, to obtain an MIM (metal-insulator-metal) structural thin film having a low dielectric constant for use in the measurement of dielectric constants. The capacitance of the thin film thus obtained was measured at frequencies of about 10 kHz, 100 kHz and 1 MHz using a Precision LCR meter (HP4284A) equipped with a micromanipulator 6200 probe station. In addition, the thickness of the thin film was measured using a prism coupler. The dielectric constant was calculated from the following equation:

$$k = \frac{C \times d}{{ɛ}_{0} \times A}$$

Wherein k is a dielectric constant as a relative permittivity, C is a capacitance, ε₀ is a dielectric constant in a vacuum (ε₀=8.8542×10⁻¹² Fm⁻¹), d is a thickness of an insulating film, and A is a cross-sectional area in contact with an electrode.

2) Hardness and Elastic Modulus

The hardness and elastic modulus of the thin film were quantitatively analyzed using a nanoindenter II available from MTS Co. Ltd. The thin film was indented with the nanoindenter, and the hardness and elastic modulus of the thin film were measured when the indented depth was 10% of the film thickness. The thickness of the thin film was measured using a prism coupler. In Examples and Comparative Examples, to assure the reliability of the thin film, six spots on the insulating film were indented, from which the average value was determined to measure the hardness and elastic modulus of each film.

TABLE 1

| Ex. | Siloxane | | | | Calcination | |
|---|---|---|---|---|---|---|
| No. | Monomer*¹ | Porogen | Solvent | Preheating Conditions | Conditions | XRD Peak |
| 1 | 6 | Brij-56*² | Ethanol | 83° C. 1 min, 250° C. 1 min | 400° C. 1 hr | |
| 2 | 6 | Brij-56 | Ethanol | 83° C. 1 min, 250° C. 1 min | 420° C. 1 hr | |
| 3 | 6 | Brij-56 | Ethanol | 83° C. 1 min | 400° C. 1 hr | ∘ |
| 4 | 6 | Brij-56 | Ethanol | 150° C. 1 min, 250° C. 1 min | 400° C. 1 hr | |
| 5 | 6 | Brij-56 | Propanol | 102° C. 1 min, 250° C. 1 min | 400° C. 1 hr | |
| 6 | 6 | Brij-56 | Propanol | 102° C. 1 min, 250° C. 1 min | 420° C. 1 hr | |
| 7 | 6 | Brij-56 | Butanol | 123° C. 1 min, 250° C. 1 min | 400° C. 1 hr | |
| 8 | 6 | Brij-56 | Butanol | 123° C. 1 min, 250° C. 1 min | 420° C. 1 hr | |
| 9 | 6 | Brij-56 | Pentanol | 143° C. 1 min, 250° C. 1 min | 400° C. 1 hr | |
| 10 | 6 | Brij-56 | Pentanol | 143° C. 1 min, 250° C. 1 min | 420° C. 1 hr | |
| 11 | 6 | tCD*³ | PGMEA*⁵ | 150° C. 1 min, 250° C. 1 min | 400° C. 1 hr | |
| 12 | 6 | tCD | PGMEA | 150° C. 1 min, 250° C. 1 min | 420° C. 1 hr | |
| 13 | 6 | Triton*⁴ | PGMEA | 150° C. 1 min, 250° C. 1 min | 400° C. 1 hr | |
| 14 | 6 | Triton | PGMEA | 150° C. 1 min, 250° C. 1 min | 420° C. 1 hr | |
| 15 | 12 | Brij-56 | Ethanol | 83° C. 1 min | 400° C. 1 hr | ∘ |
| 16 | 6 + 14 | Brij-56 | Ethanol | 83° C. 1 min | 400° C. 1 hr | ∘ |
| 17 | 6 + 17 | Brij-56 | Ethanol | 83° C. 1 min | 400° C. 1 hr | ∘ |
| 18 | 6 | Brij-56 | Ethanol | 40° C. 6 hrs | 450° C. 4 hrs | ∘ |
| 19 | 6 | Brij-56 | Propanol | 40° C. 6 hrs | 450° C. 4 hrs | |
| 20 | 6 | Brij-56 | Butanol | 40° C. 6 hrs | 450° C. 4 hrs | |
| 21 | 6 | Brij-56 | Pentanol | 40° C. 6 hrs | 450° C. 4 hrs | |

*¹Note:
the number represented in each cell of the siloxane monomer column shows Formula No.
*²Brij-56: polyoxyethylene(10) cetyl ether
*³tCD: heptakis(2,3,6-tri-O-methyl)-β-cyclodextrin
*⁴Triton: 4-octylphenol ethoxylate
*⁵PGMEA: propylene glycol methyl ether

TABLE 2

| | Dielectric | Thickness | Hardness | Modulus |
|---|---|---|---|---|
| Ex. No. | Constant | (Å) | (Gpa) | (Gpa) |
| 1 | 2.2 | 8165 | 1.01 | 6.51 |
| 2 | 2.1 | 8100 | 1.10 | 7.04 |
| 3 | 2.2 | 7783 | 1.23 | 7.83 |
| 4 | 2.2 | 7809 | 1.07 | 7.20 |
| 5 | 2.2 | 6243 | 0.92 | 6.10 |
| 6 | 2.1 | 6187 | 1.09 | 6.98 |
| 7 | 2.2 | 4418 | 0.94 | 6.33 |
| 8 | 2.2 | 4379 | 0.96 | 6.36 |
| 9 | 2.3 | 3207 | 0.88 | 6.26 |
| 10 | 2.3 | 3198 | 0.89 | 6.18 |
| 11 | 2.7 | 3878 | 0.84 | 6.36 |
| 12 | 2.6 | 3904 | 1.84 | 6.14 |
| 13 | 2.6 | 3776 | 1.11 | 7.69 |
| 14 | 2.5 | 3745 | 1.13 | 7.82 |
| 15 | 2.2 | 7532 | 1.15 | 7.21 |
| 16 | 2.3 | 7625 | 1.08 | 6.95 |
| 17 | 2.2 | 7466 | 1.05 | 6.88 |
| 18 | 2.3 | 4826 | 1.76 | 11.62 |
| 19 | 2.2 | 4132 | 1.60 | 10.68 |
| 20 | 2.3 | 3584 | 1.59 | 10.82 |
| 21 | 2.2 | 2724 | 1.61 | 10.74 |

Analysis Of Moisture Absorbency Of Thin Film

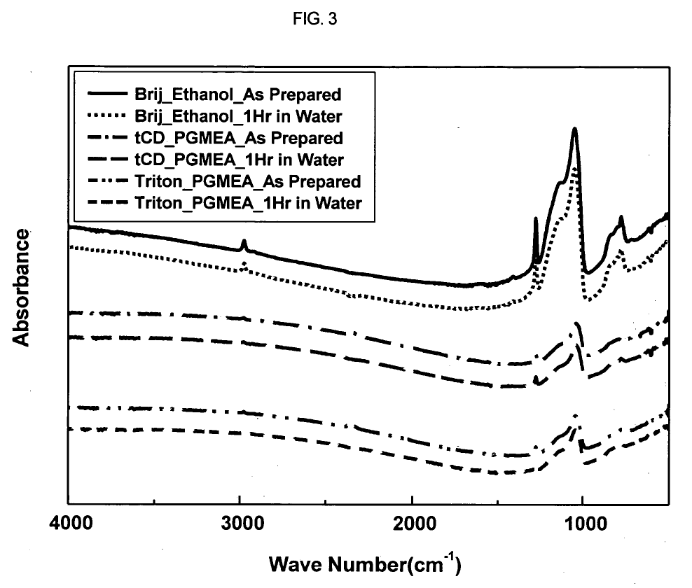

The thin films prepared in Examples 1, 11 and 13 were dipped into water and allowed to stand for 1 hr. Whether a peak corresponding to an —OH group had been generated was confirmed by measuring the absorbance using an FTIR spectrometer. The results are shown in FIG. 3.

As is apparent from the graph of FIG. 3, the mesoporous thin films prepared by the method of an embodiment of the present invention have no peak corresponding to the —OH group even after being dipped into water for 1 hr, just as when not dipped. Thus, a mesoporous thin film of embodiments of the present invention is confirmed to have basically no moisture absorbency.

As described hereinbefore, embodiments of the present invention provide a method of preparing a mesoporous thin film having a low dielectric constant. The thin film thus obtained has low or no moisture absorbency and high quality at a monomer level. Therefore, a method of embodiments of the present invention is advantageous because it has low preparation costs, without the need for polymerization and moisture absorption prevention. Further, the use of a surfactant may result in the formation of an ordered structure, whereby the thin film has high hardness and may be applied to various fields requiring ordered structures. Consequently, since a mesoporous thin film prepared according to embodiments of the present invention has a low dielectric constant and excellent mechanical properties including elastic modulus and hardness, it may be readily applied to semiconductor manufacturing processes.

Although a preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method of preparing a mesoporous thin film having a low dielectric constant, comprising:
a first step of mixing at least one cyclic siloxane-based monomer selected from the group consisting of monomers represented by Formula 1, 2 and 3, below, with an organic solvent, an acid catalyst or a base catalyst, and water, to prepare a coating solution; and
a second step of applying the coating solution on a substrate, and heat curing the coating solution applied on the substrate, to obtain a thin film: 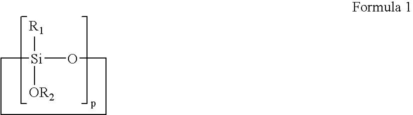
wherein R₁ is a hydrogen atom, a C1 to C3 alkyl group, or a C6 to C15 aryl group; R₂ is a hydrogen atom, a C1 to C10 alkyl group, or SiX₁X₂X₃ (in which X₁, X₂ and X₃ are independently each a hydrogen atom, a C1 to C3 alkyl group, a C1 to C10 alkoxy group, or a halogen atom); and p is an integer ranging from 3 to 8; 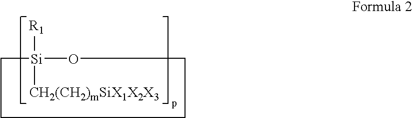
wherein R₁ is a hydrogen atom, a C1 to C3 alkyl group, or a C6 to C15 aryl group; X₁, X₂ and X₃ are independently each a hydrogen atom, a C1 to C3 alkyl group, a C1 to C10 alkoxy group, or a halogen atom, at least one of which is a hydrolyzable functional group; and m is an integer ranging from 0 to 10, and p is an integer ranging from 3 to 8; and 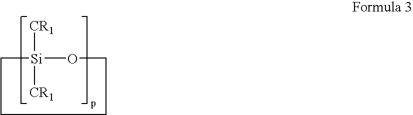
wherein R₁ is a hydrogen atom, a C1 to C3 alkyl group, R′CO (in which R′ is a C1 to C3 alkyl group), a halogen atom, or SiX₁X₂X₃ (in which X₁, X₂ and X₃ are independently each a hydrogen atom, a C1 to C3 alkyl group, a C1 to C10 alkoxy group, or a halogen atom, at least one of which is a hydrolysable functional group); and p is an integer ranging from 3 to 8.

2. The method as set forth in claim 1, wherein the first step of mixing further comprises adding a porogen.

3. The method as set forth in claim 1, wherein the first step of mixing further comprises adding one or a combination of both of a compound represented by Formula 4, below, and a compound represented by Formula 5, below:
X₃X₂X₁Si-M-SiX₁X₂X₃ Formula 4
wherein X₁, X₂ and X₃ are independently each a hydrogen atom, a C1 to C3 alkyl group, a C1 to C10 alkoxy group, or a halogen atom, at least one of which is a hydrolyzable functional group; and M is a single bond, a C1 to C10 alkylene group, or a C6 to C15 arylene group; and
(R₁)ₙSi(OR₂)₄₋ₙ Formula 5
wherein R₁ is a hydrogen atom, a C1 to C3 alkyl group, a halogen group, or a C6 to C15 aryl group, and R₂ is a hydrogen atom, a C1 to C3 alkyl group, or a C6 to C15 aryl group, at least one of R₁ and OR₂ is a hydrolyzable functional group; and n is an integer ranging from 0 to 3.

4. The method as set forth in claim 1, wherein the monomer represented by Formula 1 is at least one selected from the group consisting of compounds represented by Formulas 6 to 11, below,
the monomer represented by Formula 2 is a compound represented by Formula 12, below, and
the monomer represented by Formula 3 is a compound represented by Formula 13, below:

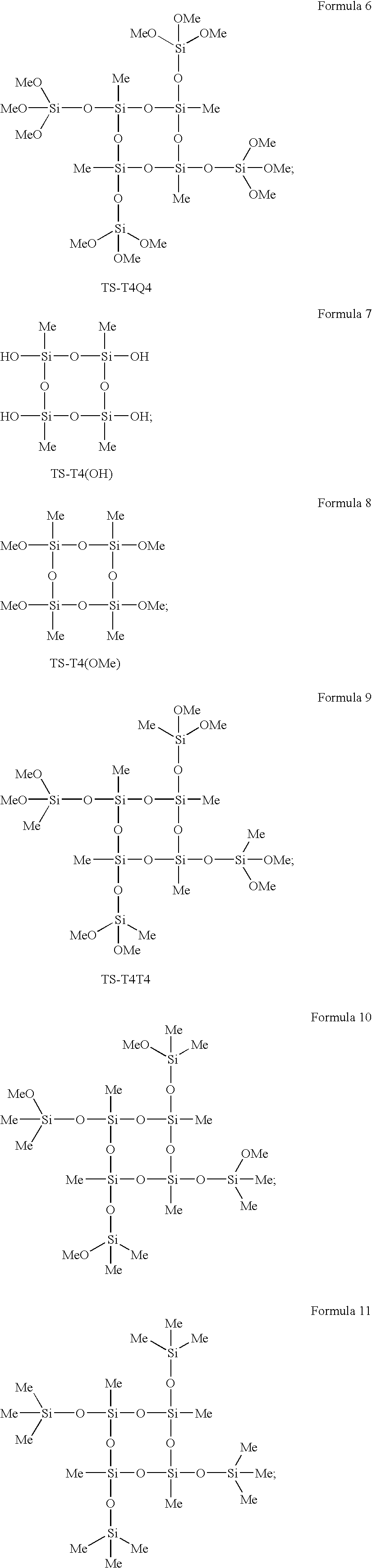

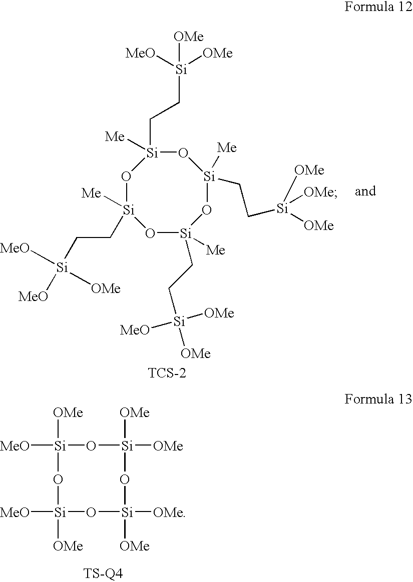

5. The method as set forth in claim 2, wherein the monomer represented by Formula 1 is at least one selected from the group consisting of compounds represented by Formulas 6 to 11, below,
the monomer represented by Formula 2 is a compound represented by Formula 12, below, and
the monomer represented by Formula 3 is a compound represented by Formula 13, below:

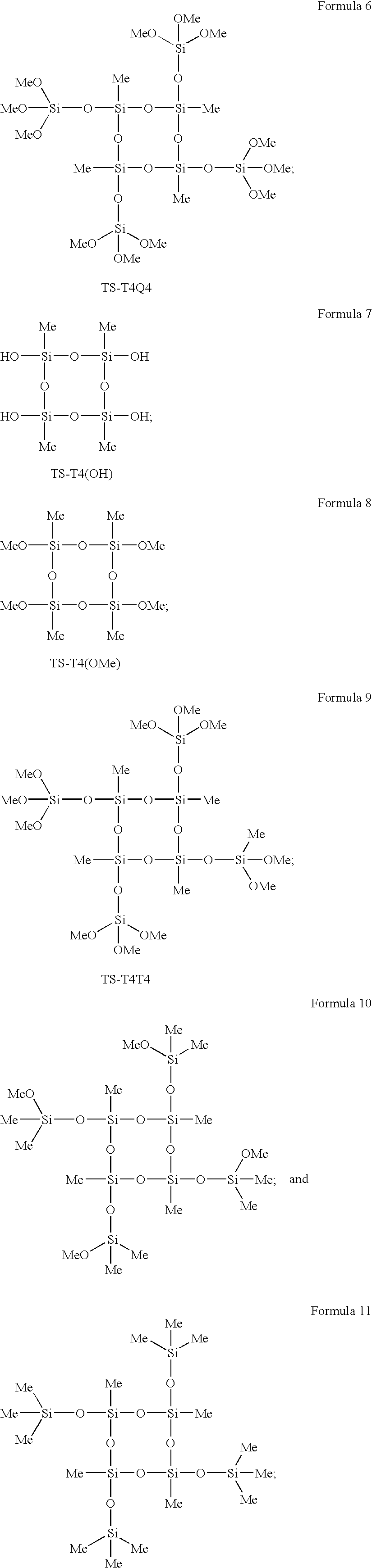

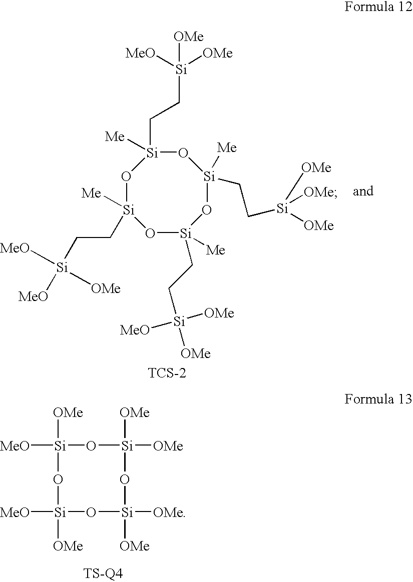

6. The method as set forth in claim 3, wherein the monomer represented by Formula 4 is a compound represented by Formula 14 or 15, below, and
the siloxane monomer represented by Formula 5 includes any one selected from the group consisting of compounds represented by Formulas 16, 17 and 18, below:

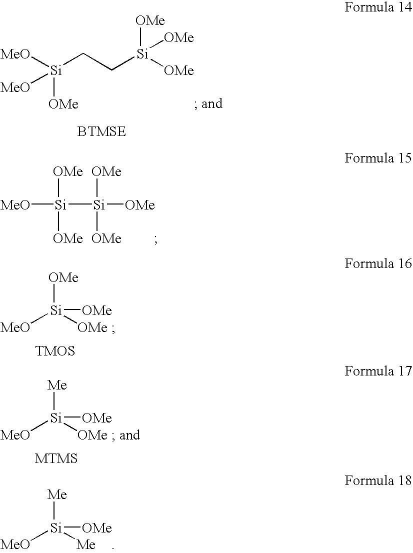

7. The method as set forth in claim 2, wherein the porogen is selected from the group consisting of polycaprolactone, α-cyclodextrin, β-cyclodextrin, and γ-cyclodextrin.

8. The method as set forth in claim 2, wherein the porogen comprises at least one surfactant selected from the group consisting of sulfates, sulfonates, phosphates, carboxylic acids, alkylammonium salts, Gemini surfactants, cetylethylpiperidinium salts, dialkyldimethylammonium, primary amines, poly(oxyethylene)oxide, octaethylene glycol monodecyl ether, octaethylene glycol monohexadecyl ether, and block copolymers.

9. The method as set forth in claim 1, wherein the acid catalyst is selected from the group consisting of hydrochloric acid, nitric acid, benzene sulfonic acid, oxalic acid, formic acid, and combinations thereof, and
the base catalyst is selected from the group consisting of potassium hydroxide, sodium hydroxide, triethylamine, sodium bicarbonate, pyridine, and combinations thereof.

10. The method as set forth in claim 1, wherein the organic solvent is selected from the group consisting of aliphatic hydrocarbon solvents, including hexane or heptane; aromatic hydrocarbon solvents, including anisole, mesitylene or xylene; ketone-based solvents, including methyl isobutyl ketone, 1-methyl-2-pyrrolidinone, cyclohexanone or acetone; ether-based solvents, including tetrahydrofuran or isopropyl ether; acetate-based solvents, including ethyl acetate, butyl acetate or propylene glycol methyl ether acetate; alcohol-based solvents, including isopropyl alcohol or butyl alcohol; amide-based solvents, including dimethylacetamide or dimethylformamide; silicon-based solvents; and combinations thereof.

11. The method as set forth in claim 2, wherein the porogen is used in an amount of 0.01 to 70 wt %, based on the weight of the solid content of the coating solution.

12. The method as set forth in claim 1, wherein the coating solution has 5 to 70 wt % solid content, based on the total weight thereof.

13. A mesoporous dielectric thin film prepared by the method as set forth in claim 1.

14. The mesoporous dielectric thin film as set forth in claim 13, wherein the mesoporous thin film has an X-ray diffraction peak in a range of 2θ=0.3-10°.
